(19) United States
(12) Patent Application Publication
(10) Pub. No.: US 2026/0349154 A1
(43) Pub. Date: Nov. 5, 2026

(54) PHOTOSYNTHESIS-PROMOTING SHEET

(71) Applicant: TOPPAN Holdings Inc., Tokyo (JP)

(72) Inventors: Akiharu MIYANAGA, Tokyo (JP); Tetsuji ITO, Tokyo (JP)

(73) Assignee: TOPPAN Holdings Inc., Tokyo (JP)

(21) Appl. No.: 19/707,397

(22) Filed: Jun. 15, 2026

Related U.S. Application Data
(63) Continuation of application No. PCT/JP2024/044288, filed on Dec. 13, 2024.

(30) Foreign Application Priority Data
Dec. 15, 2023 (JP) 2023-211606

(51) Int. Cl. G02B 5/20; A01G 9/14; B82Y 20/00; C09K 11/02; C09K 11/88; H10H 20/851

(52) U.S. Cl. CPC G02B 5/208; C09K 11/025; C09K 11/883; A01G 9/1438; B82Y 20/00; H10H 20/8514

(57) ABSTRACT

The present disclosure aims to provide a photosynthesis-promoting sheet that is able to convert non-photosynthetically active light such as UV light into blue or red photosynthetically active light, while effectively enhancing PPFD of photosynthetically active light during the conversion. The photosynthesis-promoting sheet of the present disclosure contains quantum dots and includes a quantum dot sheet containing the quantum dots, having a first surface and a second surface facing away from the first surface, and converting non-photosynthetically active light into photosynthetically active light. The first surface is a surface exposed to sunlight; the second surface is a surface emitting the photosynthetically active light; and the quantum dot sheet contains a UV scattering agent.

### CROSS-REFERENCE TO RELATED APPLICATIONS

This application is a continuation of International Application No. PCT/JP2024/044288, filed Dec. 13, 2024, which claims priority to Japanese Application No. JP 2023-211606, filed Dec. 15, 2023. The entire contents of both prior applications are hereby incorporated by reference.

### TECHNICAL FIELD

The present disclosure relates to photosynthesis-promoting sheets containing quantum dots.

### BACKGROUND ART

Crops and seaweed use sunlight to perform photosynthesis, but not all wavelengths contained in sunlight are involved in photosynthesis; in fact, blue and red wavelengths are mainly involved in photosynthesis.

For example, PTL 1 discloses a quantum dot LED provided with a quantum dot phosphor sheet in which a polymer film containing red quantum dots is disposed on a substrate. It emits light that is a mixture of red light that has been wavelength-converted by absorbing part of the light emitted from the LED with blue light that has passed through the phosphor sheet.

### CITATION LIST

### Patent Literature

PTL 1: JP2019037243A

### SUMMARY OF THE DISCLOSURE

### Technical Problem

The configuration incorporating quantum dots to promote photosynthesis has not yet been established. For example, as described in PTL 1, it is essential to use LED light sources, but using them across a large area incurs significant costs and involves a complicated configuration.

The present disclosure has been made in light of such circumstances and aims to provide a photosynthesis-promoting sheet which is able to convert non-photosynthetically active light such as UV light contained in sunlight into blue or red photosynthetically active light, while effectively enhancing the photon flux density of the photosynthetically active light during the conversion.

### Solution to Problems

A photosynthesis-promoting sheet according to an aspect of the present disclosure is a photosynthesis-promoting sheet containing quantum dots, including a quantum dot sheet that has a first surface and a second surface facing away from the first surface and converts non-photosynthetically active light into photosynthetically active light. The first surface is exposed to sunlight; the second surface emits the photosynthetically active light; and the quantum dot sheet contains the quantum dots and a UV scattering agent.

A photosynthesis-promoting sheet according to another aspect of the present disclosure is a photosynthesis-promoting sheet containing quantum dots. It includes a quantum dot sheet that has a first surface and a second surface facing away from the first surface and converts non-photosynthetically active light into photosynthetically active light. The first surface is exposed to sunlight; the second surface is emits the photosynthetically active light; the quantum dot sheet contains at least the quantum dots; and the first surface of the quantum dot sheet is provided with a UV scattering layer.

A photosynthesis-promoting sheet according to another aspect of the present disclosure is a photosynthesis-promoting sheet containing quantum dots. It includes a quantum dot sheet that has a first surface and a second surface facing away from the first surface and converts non-photosynthetically active light into photosynthetically active light. The first surface is exposed to sunlight; the second surface emits the photosynthetically active light; the quantum dot sheet contains at least the quantum dots; and the second surface of the quantum dot sheet is provided with a dichroic filter layer reflecting UV and transmitting visible light.

### Advantageous Effects of the Disclosure

According to the photosynthesis-promoting sheet of the present disclosure, non-photosynthetically active light such as UV light contained in sunlight can be converted into blue or red photosynthetically active light, while effectively enhancing the photon flux density of the photosynthetically active light during the conversion.

### BRIEF DESCRIPTION OF THE DRAWINGS

FIG. 1 is a set of schematic diagrams illustrating light intensity of photosynthetically-effective wavelengths and photosynthesis rate.

FIG. 2 is a set of cross-sectional views each illustrating a photosynthesis-promoting sheet according to the present embodiment.

FIG. 3 is a graph showing conversion into photosynthetically active light (red light) according to Experimental Example 1.

FIG. 4 is a graph showing conversion into photosynthetically active light (blue light) according to Experimental Example 2.

FIG. 5 is a graph showing relationship between wavelength and transmittance with and without a UV scattering layer.

FIG. 6 is a schematic diagram illustrating a spectral distribution measurement method.

FIG. 7 shows spectral distribution diagrams of respective sample sheets immediately after start of the experiment.

FIG. 8 shows spectral distribution diagrams of respective sample sheets two years later.

FIG. 9 is a graph showing relationship between wavelength and light intensity ratio of respective sample sheets.

FIG. 10 is a graph showing optical properties (transmittance) of respective quantum dot sheets containing blue quantum dots around a wavelength of 430 nm.

FIG. 11 is a graph showing optical properties (transmittance) of respective quantum dot sheets containing blue quantum dots at wavelengths of 480 nm or more.

### DESCRIPTION OF THE EMBODIMENTS

Hereinafter, some embodiments of the present disclosure (hereinafter referred to as embodiments) will be described in detail. It should be noted that the present disclosure should not be limited to the following embodiments, but can be modified in various ways and implemented without departing from the spirit of the disclosure. In the present specification, the term light intensity or photon flux density refers to photosynthetic photon flux density (PPFD).

A photosynthesis-promoting sheet according to the present embodiment can perform wavelength conversion of non-photosynthetically active light such as UV light contained in sunlight into photosynthetically active light such as blue light and red light and can effectively promote photosynthesis of photosynthetic targets such as crops, seaweed, and the like. The term “sheet” generally defines a configuration whose thickness is small relative to its length and width. The term “sheet” can also be read as “film.” The photosynthesis-promoting sheet according to the present embodiment is preferably flexible. This makes it possible to variously change the mode of the photosynthesis-promoting sheet according to usage.

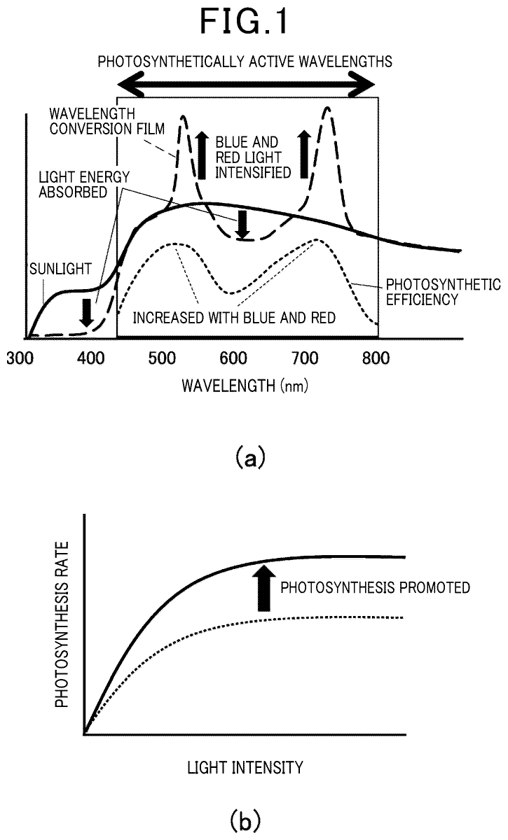

As shown in FIG. 1, the light involved in photosynthesis is red light and blue light; but sunlight contains photosynthetically active wavelengths and non-photosynthetically active light such as UV light outside the photosynthetically active wavelengths. Therefore, if the light energy of the non-photosynthetically active wavelengths is absorbed and converted to the wavelengths of blue light and red light to increase the light intensity of the photosynthetically active wavelengths, photosynthesis rate can be increased to promote photosynthesis. Thus, growth of crops, seaweed, and the like can be promoted and their quality can be improved.

In this regard, the present inventors have developed a photosynthesis-promoting sheet which is able to directly use sunlight to convert non-photosynthetically active light into photosynthetically active light without using any LED light sources and to deliver light that is optimal for the growth of photosynthetic targets.

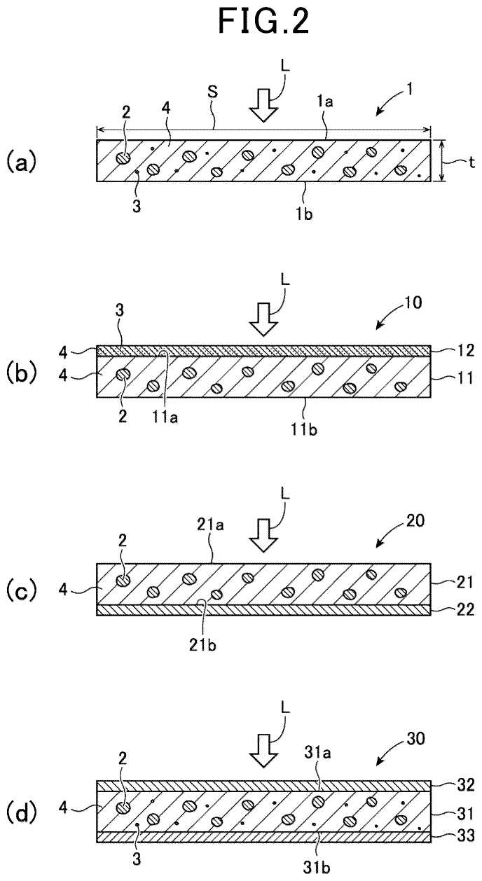

FIG. 2(a) shows a photosynthesis-promoting sheet 1 according to a first embodiment. As shown in FIG. 2(a), the photosynthesis-promoting sheet 1 includes a first surface 1a and a second surface 1b which are opposed to each other in the thickness direction. The first and second surfaces 1a and 1b are preferably flat; but they can be curved according to usage or the like. The first surface 1a is the surface on the side exposed to sunlight L, and the second surface 1b is the surface on the side facing photosynthetic targets and emits photosynthetically active light to the photosynthetic targets. Thus, in the present embodiment, the photosynthesis-promoting sheet 1 is exposed to the sunlight L, and the non-photosynthetically active light contained in the sunlight L is ensured to be converted into photosynthetically active wavelengths. The first surface 1a of the photosynthesis-promoting sheet 1 may be directly exposed to the sunlight L or may be exposed to the sunlight L using reflection or the like. Alternatively, a component for adjusting the light energy of the sunlight L may be placed in front of the first surface 1a of the photosynthesis-promoting sheet 1, so that the first surface 1a is exposed to the sunlight L via the component.

The photosynthesis-promoting sheet 1 contains a resin 4 which contains quantum dots 2 and an ultraviolet (UV) scattering agent 3.

The quantum dots 2 have fluorescent properties due to band-edge emission and exhibit a quantum size effect due to their particle size.

Quantum dots refer to nanoparticles having a particle size of several nm to several tens of nm. For example, quantum dots may be those of CdS, CdSe, ZnS, ZnSe, ZnSeS, ZnTe, ZnTeS, InP, AgInS₂, CuInS₂, or the like, or may be those having structures in which such quantum dots as cores are covered with shells. Because of the toxicity of Cd, its use is restricted in various countries, and therefore it is preferable that Cd is not contained in the quantum dots.

It is preferable that a number of organic ligands are coordinated to the surfaces of the quantum dots 2. This can suppress aggregation of quantum dots 2 and desired optical properties can be exhibited. Ligands that can be used in reactions are not particularly limited but, for example, the following ligands may be typically used.

Aliphatic primary amines, oleylamine: C₁₈H₃₅NH₂, stearyl (octadecyl)amine: C₁₈H₃₇NH₂, dodecyl (lauryl)amine: C₁₂H₂₅NH₂, decylamine: C₁₀H₂₁NH₂, and octylamine: C₈H₁₇NH₂ Fatty acids, oleic acid: C₁₇H₃₃COOH, stearic acid: C₁₇H₃₅COOH, palmitic acid: C₁₅H₃₁COOH, myristic acid: C₁₃H₂₇COOH, lauryl (dodecanoic) acid: C₁₁H₂₃COOH, decanoic acid: C₉H₁₉COOH, and octanoic acid: C₇H₁₅COOH

Thiols, octadecanethiol: C₁₈H₃₇SH, hexanedecanethiol: C₁₆H₃₃SH, tetradecanethiol: C₁₄H₂₉SH, dodecanethiol: C₁₂H₂₅SH, decanethiol: C₁₀H₂₁SH, and octanethiol: C₈H₁₇SH Phosphines, trioctylphosphine: (C₈H₁₇)₃P, triphenylphosphine: (C₆H₅)₃P, and tributylphosphine: (C₄H₉)₃P

Phosphine oxides, trioctylphosphine oxide: (C₈H₁₇)₃P═O, triphenylphosphine oxide: (C₆H₅)₃P═O, and tributylphosphine oxide: (C₄H₉)₃P═O

The quantum dots 2 may have a core-shell structure. Specifically, in the structure, a core located in the center may be surrounded and covered with a shell. In the core-shell structure, a number or organic ligands can be coordinated to the shell surfaces. The core may be formed, for example, of the materials mentioned above, and the shell may be formed, for example, of zinc sulfide (ZnS) or the like, although the material is not important. Similarly to the core, it is also preferable that the shell does not contain cadmium (Cd).

The wavelength conversion range of the quantum dots 2 can be adjusted by changing the particle size even when they are composed of the same material. Accordingly, in order to achieve optimal photosynthetic wavelengths for each photosynthetic target, the quantum dots 2 can be configured to achieve optimal wavelength conversion by adjusting the particle size of the quantum dots 2.

In the present embodiment, the quantum dots 2 preferably contain at least red quantum dots emitting red light. Thus, non-photosynthetically active light can be appropriately converted to red light. Red light has a wavelength of about 640 nm to 770 nm, and for example, quantum dots 2 capable of covering wavelengths around 670 nm can be selected.

It is more preferable that the quantum dots 2 contain both of red quantum dots emitting red light and blue quantum dots emitting blue light. Thus, non-photosynthetically active light can be appropriately converted to both of red light and blue light. Blue light has a wavelength of about 380 nm to 500 nm, and for example, quantum dots 2 capable of covering wavelengths around 430 nm can be selected.

The content of the quantum dots 2 in the photosynthesis-promoting sheet 1 is preferably 1 mass % or more and 10 mass % or less, and more preferably 2 mass % or more and 8 mass % or less. As will be described later, if the photosynthesis-promoting sheet has a multi-layer structure, the content of the quantum dots can be specified by the content in the quantum dot sheet.

The UV scattering agent 3 is a component having a property for scattering UV light. The UV scattering agent that can be applied to the present embodiment may be nanoparticles of titanium oxide, zirconium oxide, zinc oxide, cerium oxide, silica, or the like, of which at least one may be used, or two or more may be used in combination. In particular, nanoparticles of titanium oxide (titania) or zirconium oxide (zirconia) are preferably applied.

Thus, one of the features of the photosynthesis-promoting sheet 1 according to the present embodiment is that it contains the UV scattering agent 3 for scattering UV light that is non-photosynthetically active light. Specifically, in the present embodiment, due to the photosynthesis-promoting sheet 1 being exposed to the sunlight L, UV light that is non-photosynthetically active light contained in the sunlight L is also absorbed by the photosynthesis-promoting sheet 1; but due to the photosynthesis-promoting sheet 1 containing the UV scattering agent 3, scattering of UV light inside the photosynthesis-promoting sheet 1 can be enhanced, so that the quantum dots 2 can effectively absorb UV light for conversion into red or blue photosynthetically active light.

As shown in FIG. 2(a), the quantum dots 2 and the UV scattering agent 3 are scattered throughout the resin 4. An amorphous resin is preferably used as the resin 4. The amorphous resin may have a high transparency. In general, resins having a total light transmittance of 85% or more are preferably used, but it is not limited thereto. The amorphous resin that can be used include those resins which can be used for melt extrusion molding, such as cyclic polyolefin polymer (cyclic olefin polymer: COP), cyclic polyolefin copolymer (cyclic olefin copolymer: COC), polystyrene (poly(styrene): PS), acrylic resin, polycarbonate (poly(carbonate): PC), modified polyphenylene ether (modified-poly(phenyleneether): PPE), polyethylene terephthalate (poly(ethylene terephthalate: PET), ethylene vinyl alcohol (EVAL), polymethylpentene (PMP), and highly transparent semi-crystalline resins such as polyethylene (PE), polypropylene (PP), and polyvinylidene fluoride (PVDF).

From the perspective of dispersion of the quantum dots 2 in the resin 4 or fluorescence intensity after dispersion, the amorphous resin constituting the resin mold in which the quantum dots 2 are dispersed is preferably an acrylic resin, cyclic olefin resin homopolymer (COP) or copolymer (COC), or polyethylene terephthalate (PET), or more preferably polycarbonate (PC) when heat resistance is concerned.

Use of an acrylic resin can protect the sheet from external damage. Alternatively, forming the sheet using polyethylene terephthalate (PET), ethylene vinyl alcohol (EVAL), or the like can exhibit a function as a barrier layer against water or oxygen. Alternatively, forming the sheet using PET, polycarbonate (PC), cyclic polyolefin (COP), cyclic polyolefin copolymer (COC), or the like can achieve a sheet less likely to cause cracking to thereby improve handleability of the sheet.

Various types of the resin 4 to be applied can be selected depending on the usage environment. For example, for outdoor applications, acrylic resins or PET, or mixtures of these resin components, may be used in order to obtain barrier properties or protect the sheet from external damage.

The photosynthesis-promoting sheet 1 shown in FIG. 2(a) can be formed using extrusion molding, for example. Specifically, a resin composition obtained by mixing quantum dots 2 and a UV scattering agent 3 into a resin 4 can be molded into a quantum dot sheet using an extruder. The photosynthesis-promoting sheet 1 preferably contains a metal soap. This can improve release properties when performing extrusion molding. The metal soap is not limited, but at least one material can be appropriately selected from lithium stearate, magnesium stearate, calcium stearate, barium stearate, zinc stearate, calcium laurate, barium laurate, and the like.

Alternatively, a quantum dot sheet can be formed by applying a resin composition obtained by mixing quantum dots 2 and a UV scattering agent 3 in a resin 4 onto the surface of a substrate and removing the substrate after curing.

In the present embodiment, thickness dimension t of the photosynthesis-promoting sheet 1 is not particularly limited but it can be reduced to around 50 μm to 2,000 μm. The photosynthesis-promoting sheet 1 may be obtained using molding or coating. The length dimension S of one side of the photosynthesis-promoting sheet 1 is not particularly limited but it can be changed depending on usage. For example, a greenhouse can be constructed using the photosynthesis-promoting sheet 1 of the present embodiment. In this case, a composition for forming the photosynthesis-promoting sheet 1 can be applied to glass, or the photosynthesis-promoting sheet 1 can be bonded to glass or provided to the ceiling. The shape of the photosynthesis-promoting sheet 1 as viewed in plan view may be rectangular, square, polygonal, circular, or elliptical, or may be in other shapes. The shape of the photosynthesis-promoting sheet 1 can be adjusted in various ways depending on usage, or the like. In particular, in the present embodiment, the photosynthesis-promoting sheet 1 can be formed using extrusion molding or coating, and therefore the shape and size can be easily adjusted, thereby achieving high productivity and high production efficiency.

A photosynthesis-promoting sheet 10 shown in FIG. 2(b) includes a quantum dot sheet 11 having a first surface 11a and a second surface 11b and containing the quantum dots 2 that convert non-photosynthetically active light into photosynthetically active light, and a UV scattering layer 12 disposed on the first surface 11a of the quantum dot sheet 11. In FIG. 2(b), reference signs similar to those of FIG. 2(a) indicate the same components.

In the photosynthesis-promoting sheet 10 shown in FIG. 2(b), the UV scattering layer 12 is disposed on the first surface 11a of the quantum dot sheet 11 that is the surface on the side exposed to the sunlight L. Due to this disposition, UV light contained in the sunlight L is appropriately scattered before it reaches the quantum dot sheet 11, and therefore the UV light can be effectively absorbed in the quantum dot sheet 11 and converted into red or blue photosynthetically active light.

In FIG. 2(b), similarly to FIG. 2(a), the UV scattering agent 3 may also be contained in the quantum dot sheet 11 together with the quantum dots 2; however, the content may be lower compared to FIG. 2(a). The amount of the UV scattering agent 3 per unit volume is preferably larger in the UV scattering layer 12 than in the quantum dot sheet 11.

The UV scattering layer 12 can be formed with a structure in which the UV scattering agent 3 is dispersed in the resin 4. The resin 4 constituting the quantum dot sheet 11 and the UV scattering layer 12 may be the same material or different materials; however, using the same material is preferable because this can enhance adhesion between the quantum dot sheet 11 and the UV scattering layer 12. Alternatively, if different materials are used for the resin 4, for example, an acrylic resin may be used for the resin 4 in the UV scattering layer 12 on the sunlight L side to achieve protection against external damage, and a polyethylene terephthalate resin (PET), ethylene vinyl alcohol (EVAL), or the like having high barrier properties may be used for the resin 4 in the quantum dot sheet 11 in order to suppress deterioration due to moisture or oxygen.

For the photosynthesis-promoting sheet 10 shown in FIG. 2(b), the quantum dot sheet 11 and the UV scattering layer 12 can be formed integrally using coextrusion molding. Alternatively, the quantum dot sheet 11 and the UV scattering layer 12 can also be formed using coating. Alternatively, an inorganic material such as TiO₂ or ZrO₂ may be deposited on the first surface 11a of the quantum dot sheet 11 to form a UV scattering layer 12.

A photosynthesis-promoting sheet 20 shown in FIG. 2(c) includes a quantum dot sheet 21 having a first surface 21a and a second surface 21b and containing the quantum dots 2 that convert non-photosynthetically active light into photosynthetically active light, and a dichroic filter layer 22 disposed on the second surface 21b of the quantum dot sheet 21. In FIG. 2(c), reference signs similar to those of FIG. 2(a) indicate the same components.

The dichroic filter layer 22 has a property for reflecting UV light and transmitting visible light. As an example, the dichroic filter layer 22 may be a multi-layer film in which TiO₂ having high refractive index and SiO₂ having low refractive index are alternately laminated. TiO₂ and SiO₂ are both transparent materials.

In the photosynthesis-promoting sheet 20 shown in FIG. 2(c), when the first surface 21a of the quantum dot sheet 21 is exposed to the sunlight L, non-photosynthetically active light is wavelength-converted into photosynthetically active light by the quantum dots 2 contained in the quantum dot sheet 21. In this case, part of the UV light that has passed through the quantum dot sheet 21 is reflected by the dichroic filter layer 22. The reflected UV light is converted to red or blue light by the quantum dots 2 in the quantum dot sheet 21. Therefore, the intensity of the UV light emitted to the photosynthetic target from the second surface 21b side of the quantum dot sheet 21 can be reduced as much as possible.

The structures shown in FIG. 2(c) and 2(b) can be combined together to form a UV scattering layer 12 on the first surface and a dichroic filter layer 22 on the second surface of the quantum dot sheet. This enables even more effective conversion of non-photosynthetically active light into photosynthetically active light.

The photosynthesis-promoting sheet 20 shown in FIG. 2(c) can also be formed using coextrusion molding or coating.

In a photosynthesis-promoting sheet 30 shown in FIG. 2(d), substrates 32 and 33 are respectively disposed on a first surface 31a and a second surface 31b of a quantum dot sheet 31.

As shown in FIG. 2(d), in the quantum dot sheet 31, the quantum dots 2 and the UV scattering agent 3 are dispersed in the resin 4. As to the materials of the quantum dots 2, the UV scattering agent 3, and the resin 4, refer to the description provided referring to FIG. 2(a).

The quantum dot sheet 31 shown in FIG. 2(d) is a coated sheet which is obtained by applying a composition for forming the quantum dot sheet 31 to either or both of the substrates 32 and 33. If the composition for forming the quantum dot sheet 31 is applied to either one of the substrates 32 and 33, the other one of the substrates 33 and 32 is bonded to the exposed surface of the resultant quantum dot sheet 31 to form a laminated structure. If the composition for forming the quantum dot sheet 31 is applied to both of the substrates 32 and 33, the resultant parts of the quantum dot sheet 31 are bonded to each other with their inner surfaces facing inward. Thus, a laminated structure can be obtained in which the substrates 32 and 33 are disposed on respective both sides of the quantum dot sheet 31.

In FIG. 2(d), the substrate 32 or 33 may be disposed on only one surface of the quantum dot sheet 31.

The laminated sheet shown in FIG. 2(d) can be formed using coextrusion. By forming the substrates 32 and 33 using a material having excellent barrier properties, the quantum dot sheet 31 can be appropriately protected from moisture or oxygen.

The substrates 32 and 33 are both made of transparent resins selected from polyethylene terephthalate (PET) and polycarbonate (PC), although the materials are not limited to these.

The photosynthesis-promoting sheet according to the present embodiment preferably has a photon flux density of 0.6 μmol m⁻² s⁻¹ or more in the wavelength range of 400 nm or more and 500 nm or less. Preferably, it has a photon flux density of 1.0 μmol m⁻² s⁻¹ or more in the wavelength range of 600 nm or more and 700 nm or less. In this way, in the present embodiment, non-photosynthetically active light such as UV light contained in sunlight can be converted into blue or red photosynthetically active light, so that the photon flux density of the photosynthetically active light can be effectively increased.

Furthermore, the light intensity ratio between blue light and red light in the photosynthesis-promoting sheet substantially remains unchanged between the ratio measured immediately after use of the sheet and the ratio measured after several years of use (two years in the experiment), and therefore the wavelength conversion function can be sustained for a long period of time.

A method of producing the photosynthesis-promoting sheet will be described. For example, a quantum dot solution, a UV scattering agent solution, and resin pellets may be mixed and dried to obtain resin pellets coated with the quantum dots and the UV scattering agent.

Subsequently, the resin pellets may be kneaded using, for example, a twin-screw extruder, and the resulting strands may be cut with a pelletizer to obtain resin pellets in which the quantum dots and the UV scattering agent are dispersed in the resin. Then, using an extrusion molding machine, the resin pellets may be extruded from the T-die, while being melted, to obtain a photosynthesis-promoting sheet 1.

In FIG. 2(b), resin pellets in which the quantum dots are dispersed in the resin and resin pellets in which the UV scattering agent is dispersed in the resin may be fed into separate raw material inlets of a coextrusion molding machine and extruded from the T-die, while being melted, to obtain the photosynthesis-promoting sheet 10 in which the quantum dot sheet 11 is laminated with the UV scattering layer 12. The photosynthesis-promoting sheet 20 of FIG. 2(c) can also be formed using coextrusion molding or the like. Alternatively, after molding the quantum dot sheet 21 and the dichroic filter layer 22 separately, they may be bonded together.

For the photosynthesis-promoting sheet 30 shown in FIG. 2(d), a composition containing the quantum dots, the UV scattering agent, and the resin component may be applied to the surface of the substrate 33 and cured to obtain the quantum dot sheet 31. Then, another substrate 32 may be bonded to the other surface of the quantum dot sheet 31 to obtain a laminated structure in which the substrates 32 and 33 are disposed on respective both surfaces of the quantum dot sheet 31.

The photosynthesis-promoting sheet according to the present embodiment can efficiently convert non-photosynthetically active light of sunlight into photosynthetically active light, although the configuration is simple. The photosynthesis-promoting sheet, which is thin and imparted with flexibility, is also suitable for large facilities, farms, and the like where it is used under sunlight.

### EXAMPLES

The effects of the present invention will be described using examples of the present invention. The embodiments of the present invention should not be construed as being limited in any way to the following examples.

### Experimental Example 1

The following sample sheets were prepared.

### Sample Sheet 1

As Sample Sheet 1, a photosynthesis-promoting sheet having a laminated structure as shown in FIG. 2(b) was obtained, including the quantum dot sheet 11 and the UV scattering layer 12 disposed on the first surface 11a of the quantum dot sheet 11. For the quantum dots 2 contained in the quantum dot sheet 11, red light quantum dots (CdSe/ZnS (average particle size: 10 nm to 15 nm)) emitting red light were used.

The UV scattering layer 12 contained titanium oxide (spherical particles having a particle size of about 100 nm to 300 nm).

The quantum dots were contained in the quantum dot sheet 11 in an amount of about 0.1 to 0.5 mass %, and the UV scattering agent 3 was contained in the UV scattering layer 12 in an amount of about 0.5 to 2 mass %.

### Sample Sheet 2

As Sample Sheet 2, a non-wavelength conversion film was used. Sample Sheet 2 had a configuration of Sample Sheet 1 with the quantum dots removed therefrom.

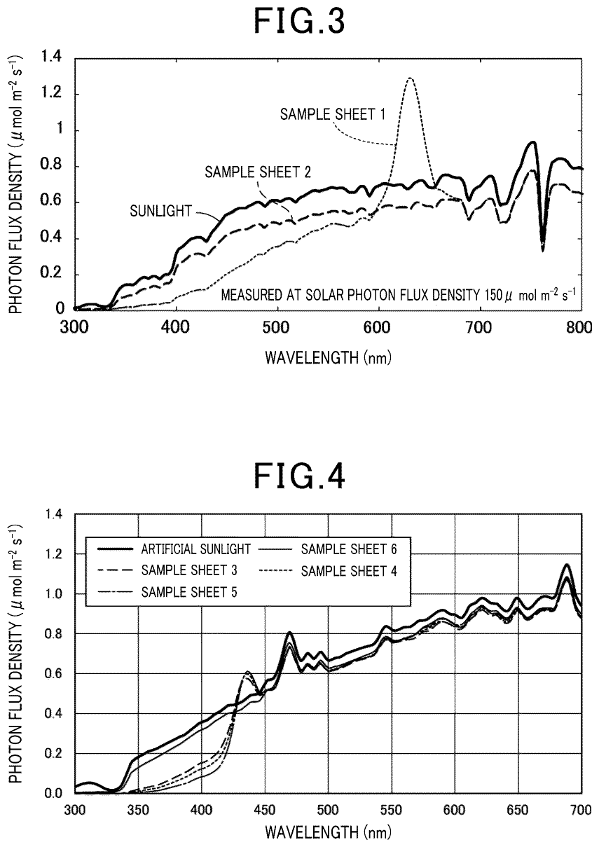

As shown in FIG. 3, it was found that, in Sample Sheet 1, the photon flux density (PPFD) of red light (having a wavelength of about 630 nm) could be effectively increased compared to that of sunlight, while sufficiently decreasing the photon flux density of non-photosynthetically active light such as UV light compared to that of sunlight. On the other hand, in Sample Sheet 2, although the photon flux density decreased in the full wavelength range compared to that of sunlight, the photon flux density of UV light was higher than in Sample Sheet 1 and the photon flux density of red light was lower than that of sunlight.

From these experimental results, Sample Sheet 1 was regarded to be Example and Sample Sheet 2 was regarded to be a Comparative Example.

### Experimental Example 2

The following sample sheets were prepared.

### Sample Sheets 3 to 5

As Sample Sheets 3 to 5, photosynthesis-promoting sheets each having a laminated structure as shown in FIG. 2(b) were obtained, including the quantum dot sheet 11 and the UV scattering layer 12 disposed on the first surface 11a of the quantum dot sheet 11. For the quantum dots 2 contained in the quantum dot sheet 11, blue light quantum dots (ZnSe/ZnSeS/ZnS (average particle size: about 10 nm to 15 nm)) emitting blue light were used.

The UV scattering layer 12 contained titanium oxide.

The thickness of Sample Sheet 3 was 125 μm, that of Sample Sheet 4 was 187.5 μm, and that of Sample Sheet 5 was 250 μm.

### Sample Sheet 6

As Sample Sheet 6, a transparent resin sheet was prepared to have a configuration of Sample Sheet 3 with the quantum dots removed therefrom.

As shown in FIG. 4, it was found that, in Sample Sheets 3 to 5, the photon flux density of blue light (having a wavelength of about 470 nm) could be effectively increased compared to that of sunlight, while sufficiently decreasing the photon flux density of non-photosynthetically active light such as UV light compared to that of sunlight. On the other hand, in Sample Sheet 6, although the photon flux density decreased in the full wavelength range compared to that of sunlight, the photon flux density of UV light was higher than in Sample Sheets 3 to 5 and the photon flux density of blue light was lower than that of sunlight.

From these experimental results, Sample Sheets 3 to 5 were regarded to be Examples and Sample Sheet 6 was regarded to be a Comparative Example.

As indicated by Sample Sheets 3 to 5, it was found that the thicker the sheet, the more the photon flux density of UV light could be decreased, and the more the photon flux density of blue light could be increased.

### Experimental Example 3

The following sample sheets were prepared.

### Sample Sheet 7

As Sample Sheet 7, a photosynthesis-promoting sheet having a laminated structure as shown in FIG. 2(b) was obtained, including the quantum dot sheet 11 and the UV scattering layer 12 disposed on the first surface 11a of the quantum dot sheet 11. The UV scattering layer 12 contained titanium oxide.

### Sample Sheet 8

The UV scattering layer was removed from Sample Sheet 7. Accordingly, Sample Sheet 8 had a single-layer structure including the quantum dot sheet 11.

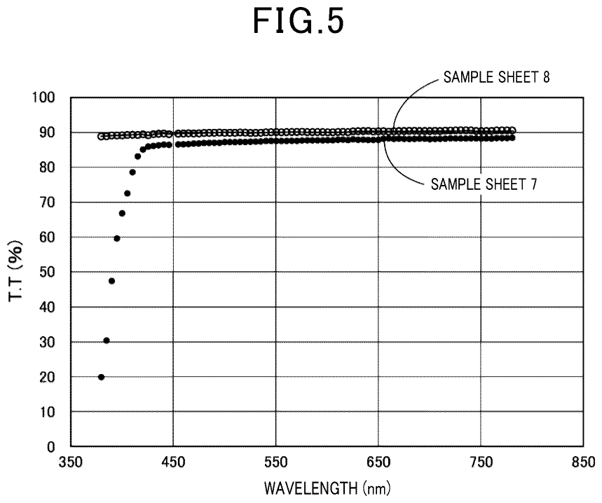

The graph of FIG. 5 shows transmittance (linear propagation of light) with and without the UV scattering layer measured by a haze meter. As shown in FIG. 5, Sample Sheet 7 exhibited a sharp drop in transmittance at the wavelengths of UV light, whereas Sample Sheet 8 maintained a flat transmittance even in the wavelength range of UV light.

From this, it was found that provision of a UV scattering layer could sufficiently reduce transmittance of UV light. From these experimental results, Sample Sheet 7 was regarded to be Example and Sample Sheet 8 was regarded to be a Comparative Example.

### Experiment 4

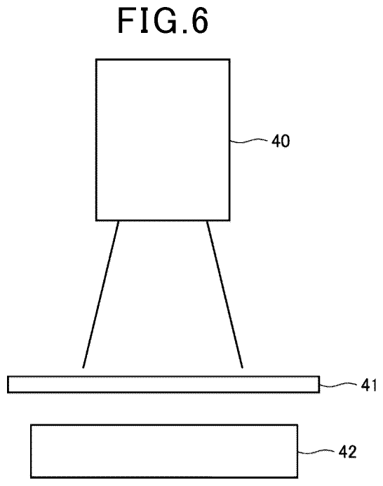

FIG. 6 is a schematic diagram illustrating a spectral distribution measurement method. The reference sign 40 in FIG. 6 indicates an artificial solar lighting device (light source) and the reference sign 42 indicates a spectroradiometer. There is a photosynthesis-promoting sheet 41 disposed between the artificial solar lighting device 40 and the spectroradiometer 42.

As the photosynthesis-promoting sheet 41, a sheet containing blue quantum dots with a peak wavelength of 420 nm, a sheet containing red quantum dots with a peak wavelength of 630 nm, and a transparent sheet containing no quantum dots were used. The quantum dots were those which were used in the above experiments.

Zirconia (having an aspect ratio of about 1.5 to 6 and having a substantially rectangular cross section with a long side being about 15 nm to 30 nm) was added as a UV scattering agent to the quantum dots-containing sheets.

For the artificial solar lighting device 40, a SOLAX XC-100BF was used. For the spectroradiometer 42, a HIDAMARI mini s-2440C was used.

In the experiment, the spectral distributions of the respective sample sheets were measured at the start of the experiment (initial stage) and were also measured after two years use in the cultivation experiment.

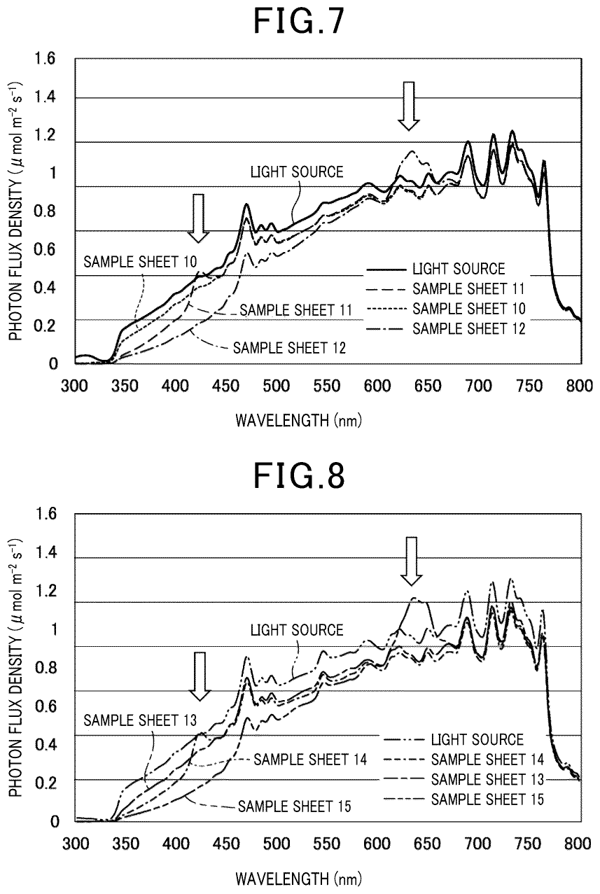

FIG. 7 is a diagram illustrating spectral distributions of the respective sample sheets immediately after start of the experiment, and FIG. 8 shows spectral distributions of them two years later. The spectral distribution of Sample Sheet 10 shown in FIG. 7 corresponds to the photon flux density of the transparent sheet. The spectral distribution of Sample Sheet 11 shown in FIG. 7 corresponds to the photon flux density of the blue quantum dot sheet. The spectral distribution of Sample Sheet 12 shown in FIG. 7 corresponds to the photon flux density of the red quantum dot sheet. The spectral distribution of Sample Sheet 13 shown in FIG. 8 corresponds to the photon flux density of the transparent sheet. The spectral distribution of Sample Sheet 14 shown in FIG. 8 corresponds to the photon flux density of the blue quantum dot sheet. The spectral distribution of Sample Sheet 15 shown in FIG. 8 corresponds to the photon flux density of the red quantum dot sheet.

As shown in FIGS. 7 and 8, it was found that, in Sample Sheets 11 and 14, the photon flux density of blue light (having a wavelength of about 470 nm) could be effectively increased, while sufficiently decreasing the photon flux density of non-photosynthetically active light such as UV light compared to that of the light source. As shown in FIGS. 7 and 8, it was found that, in Sample Sheets 12 and 15, the photon flux density of red light (having a wavelength of about 630 nm) could be effectively increased compared to that of the light source, while sufficiently decreasing the photon flux density of non-photosynthetically active light such as UV light compared to that of the light source.

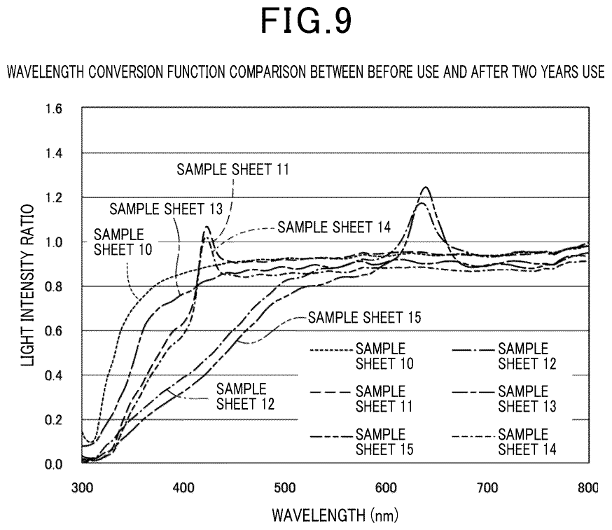

FIG. 9 is a graph showing relationship between wavelength and light intensity ratio in the respective sample sheets. The light intensity ratio was calculated as a ratio relative to the light intensity of the light source. As indicated by Sample Sheets 11 and 14 shown in FIG. 9, the light intensity ratio of blue light (having a wavelength of about 470 nm) substantially remained unchanged between the ratio measured immediately after start of the experiment and the ratio measured two years later, and as indicated by Sample Sheets 12 and 15 shown in FIG. 9, the light intensity ratio of red light (having a wavelength of about 630 nm) also substantially remained unchanged between the ratio measured immediately after start of the experiment and the ratio measured two years later. In other words, it was found that the wavelength conversion function could be sustained even after continuous use over two years.

### Experiment 5

Using a blue quantum dot sheet, an experiment on optical properties was conducted. Sample Sheet 16 as a blue quantum dot sheet contained 2.5 mass % of blue quantum dots but contained no scattering agent. Sample Sheet 17 as a blue quantum dot sheet contained 5.0 mass % of blue quantum dots but contained no scattering agent. Sample Sheet 18 as a blue quantum dot sheet contained 2.5 mass % of blue quantum dots and a scattering agent. The UV scattering agent used was zirconia (having an aspect ratio of about 1.5 to 6 and having a substantially rectangular cross section with a long side being about 15 nm to 30 nm). Sample Sheet 19 as a blue quantum dot sheet contained 2.5 mass % of blue quantum dots and a scattering agent. The UV scattering agent used was titanium oxide (spherical particles having a particle size of about 100 nm to 300 nm). Sample Sheet 19 contained the scattering agent in an amount of 0.01 mass %. In Sample Sheet 18, the scattering agent was diluted 100 times more than in Sample Sheet 19.

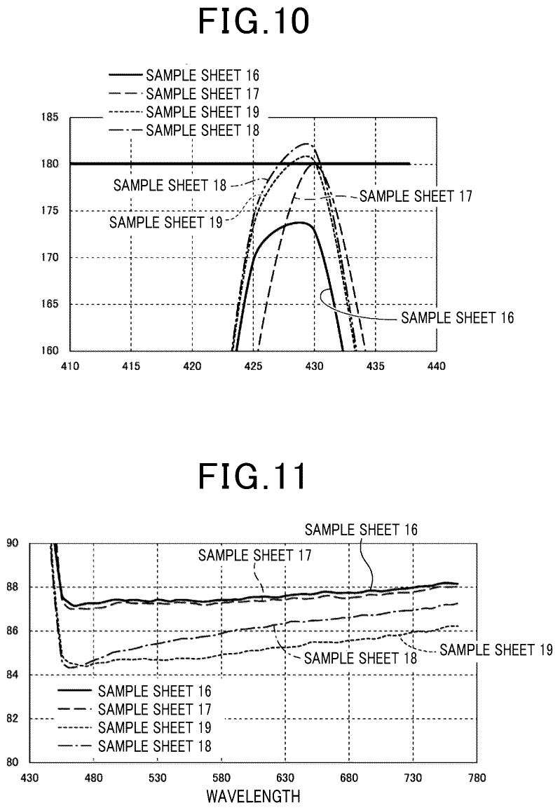

FIG. 10 is a graph showing optical properties (transmittance) of the respective quantum dot sheets containing blue quantum dots around a wavelength of 430 nm. FIG. 11 is a graph showing optical properties (transmittance) of the respective quantum dot sheets containing blue quantum dots at wavelengths of 480 nm or more.

It was found that, as shown in FIG. 10, the more the content of the quantum dots was increased, the higher the peak intensity became around the wavelength of 430 nm. Furthermore, as shown in FIG. 11, transmittance could be increased overall even at wavelengths other than 430 nm.

Furthermore, it was found that increase in dilution ratio of the scattering agent could increase the overall transmittance. The content of the scattering agent is preferably 0.00001 mass % or more and 0.001 mass % or less. The content is more preferably 0.00005 mass % or more and 0.0005 mass % or less.

### INDUSTRIAL APPLICABILITY

The photosynthesis-promoting sheet according to the present invention can efficiently convert non-photosynthetically active light contained in sunlight into photosynthetically active light, and therefore can promote photosynthesis and growth of crops or seaweed, for example, and can improve quality.

1. A photosynthesis-promoting sheet containing quantum dots, comprising
a quantum dot sheet that has a first surface and a second surface facing away from the first surface and capable of converting non-photosynthetically active light into photosynthetically active light, wherein
the first surface is suitable for being exposed to sunlight;
the second surface is capable of emitting the photosynthetically active light; and
the quantum dot sheet contains the quantum dots and a UV scattering agent.

2. The photosynthesis-promoting sheet according to claim 1,
wherein a UV scattering layer is provided on the first surface of the quantum dot sheet.

3. The photosynthesis-promoting sheet according to claim 2,
wherein a dichroic filter layer reflecting UV and transmitting visible light is provided on the second surface of the quantum dot sheet.

4. The photosynthesis-promoting sheet according to claim 1, wherein the quantum dot sheet is an extrusion-molded sheet.

5. The photosynthesis-promoting sheet according to claim 1, wherein the quantum dot sheet is a coated sheet.

6. The photosynthesis-promoting sheet according to claim 1, wherein the quantum dots include at least red light-emitting quantum dots.

7. The photosynthesis-promoting sheet according to claim 6, wherein the quantum dots additionally include blue light-emitting quantum dots.

8. The photosynthesis-promoting sheet according to claim 1, wherein
a photon flux density in a wavelength range of 400 nm or more and 500 nm or less is 0.6 μmol m⁻² s⁻¹ or more.

9. The photosynthesis-promoting sheet according to claim 1, wherein
a photon flux density in a wavelength range of 600 nm or more and 700 nm or less is 1.0 μmol m⁻² s⁻¹ or more.

10. The photosynthesis-promoting sheet according to claim 1, wherein
the quantum dots in the quantum dot sheet are present in an amount of 1 mass % or more and 10 mass % or less.

11. The photosynthesis-promoting sheet according to claim 1, wherein organic ligands are coordinated to surfaces of a plurality of the quantum dots.

12. The photosynthesis-promoting sheet according to claim 1, wherein the quantum dots have a core-shell structure.

13. The photosynthesis-promoting sheet according to claim 1, wherein the quantum dots are present in the photosynthesis-promoting sheet in an amount of 2 mass % or more and 8 mass % or less.

14. The photosynthesis-promoting sheet according to claim 1, wherein the UV scattering agent is a plurality of nanoparticles of titanium oxide or zirconium oxide.

15. The photosynthesis-promoting sheet according to claim 1, wherein the UV scattering agent is located in a UV scattering layer disposed on the first surface of the quantum dot sheet.

16. The photosynthesis-promoting sheet according to claim 15, wherein the UV scattering agent is also located in the quantum dot sheet.
